(19) United States
(12) Patent Application Publication
(10) Pub. No.: US 2017/0235635 A1
(43) Pub. Date: Aug. 17, 2017

(54) SOLID STATE STORAGE DEVICE AND DATA PROCESSING METHOD THEREOF

(71) Applicants: LITE-ON ELECTRONICS (GUANGZHOU) LIMITED, Guangzhou (CN); LITE-ON TECHNOLOGY CORPORATION, Taipei (TW)

(72) Inventor: Po-Ching Lee, Taipei (TW)

(21) Appl. No.: 15/331,941

(22) Filed: Oct. 24, 2016

(30) Foreign Application Priority Data
Feb. 17, 2016 (CN) 201610089861.0

(51) Int. Cl. G06F 11/10; G11C 29/52

(52) U.S. Cl. CPC G06F 11/1068; G11C 29/52

(57) ABSTRACT

A data processing method for a solid state storage device is provided. The solid state storage device includes a non-volatile memory having a least one data segment. The data segment includes multiple memory cells. The data processing method includes the following steps. Whether a data stored in the data segment is an invalid data is determined according to a predetermined condition. A voltage is applied to the data segment to obtain a number of the conducted memory cells under the voltage. The voltage corresponds to a preset value. Whether the data is the invalid data is determined by judging whether a relationship between the number of the conducted memory cells and the preset value satisfies the predetermined condition.

This application claims the benefit of People's Republic of China application Serial No. 201610089861.0, filed Feb. 17, 2016, the subject matter of which is incorporated herein by reference.

### TECHNICAL FIELD

The disclosure relates to a solid state storage device, especially a solid state storage device and a data processing method thereof.

### BACKGROUND

As everyone knows, a solid state device (SSD) utilizes a non-volatile memory as a main storage element. That is to say, even if the system is shut down, the data written into the non-volatile memory will be kept being stored in the solid state device.

When reading the data stored in the non-volatile memory, if a read error occurs, an error recover procedure will be performed to try to recover the stored data. In general, if the stored data was written into the non-volatile memory completely, and a data error is occurred due to the storage characteristic of the non-volatile memory, for example, loss of stored electrons. The data error caused by the storage characteristic of the non-volatile memory usually locates within certain error margins. In this kind of situation, a read error will occur during reading the stored data, and because the stored data is written into the non-volatile memory completely, the stored data can be recovered by performing the error recover procedure when the read error occurs.

However, there still are different situations that will cause the read error. The stored data could be written into the non-volatile memory incompletely, for example, if an error occurs during a writing procedure or an erase procedure, the stored data will be written into the non-volatile memory incompletely, and the stored data is defined as an invalid data. In this kind of situation, a read error will occur during reading the stored data, however, because the store data is incompletely stored, the stored data cannot be recovered by performing the error recover procedure. Therefore, as mentioned above, the error recover procedure fails to recover the stored data if the stored data is the invalid data.

Usually, when a read error occurs during reading the stored data, the error recover procedure is directly and automatically performed to try to recover the stored data regardless whether the stored data is the invalid data or not.

However, the stored data which is the invalid data cannot be recovered by the error recover procedure. Thus, the error recover procedure will take a quite lot of time to process the invalid data, but eventually the error recover procedure still cannot recover the invalid data. A lot of time is wasted, and the reading and writing efficiency of the solid state storage device is decreased.

### SUMMARY

The disclosure relates to a solid state storage device and a data processing method thereof. The access efficiency of the solid state storage device is increased by determining whether the data is the invalid data to decide if it needs to perform a data recover procedure.

According to the first aspect of the present invention, a data processing method for a solid state storage device is provided. The solid state storage device includes a non-volatile memory. The non-volatile memory has at least one data segment. The data segment includes a plurality of memory cells. The data processing method comprises the following steps. Whether a data stored in the data segment is an invalid data is determined according to a predetermined condition. The step of determining whether the data stored in the data segment is the invalid data according to the predetermined condition comprises the following steps. At least one voltage is applied to the data segment to obtain a number of the conducted memory cells under the voltage. The voltage corresponds to a preset value. Whether a relationship between the number of the conducted memory cells and the preset value satisfies the predetermined condition is judged to determine whether the data is the invalid data.

According to the second aspect of the present invention, a solid state storage device is provided. The solid state storage comprises a non-volatile memory and a controller. The non-volatile memory has at least one data segment. The data segment includes a plurality of memory cells. The controller includes an invalid determining unit for determining whether a data stored in the data segment is an invalid data according to a predetermined condition. The invalid determining unit applies at least one voltage to the data segment to obtain a number of conducted memory cells and judges whether a relationship between the number of the conducted memory cells and a preset value, which the voltage corresponds to, satisfies the predetermined condition to determine whether the data is the invalid data.

According to the third aspect of the present invention, a data processing method for a solid state storage device is provided. The solid state storage device includes a non-volatile memory. The non-volatile memory has at least one data segment. The data segment includes a plurality of memory cells. The data processing method comprises the following steps. Whether a data stored in the data segment is an invalid data is determined according to a predetermined condition. An error recover procedure is performed on the data if the data is determined not to be the invalid data and a read error occurs during reading the data. The error recover procedure is not performed on the data if the data is determined to be the invalid data and the read error occurs during reading the data.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a diagram illustrating a distribution of numbers of conducted memory cells corresponding to different read voltages applied to data segments of the non-volatile memory.

FIG. 2 shows a diagram illustrating a distribution of numbers of conducted memory cells corresponding to different read voltages applied to data segments storing a valid data and data segments storing an invalid data.

FIG. 3 shows a diagram illustrating a solid state storage device according to an embodiment of this disclosure.

FIG. 4 shows a flowchart illustrating a data processing method according to an embodiment of this disclosure.

FIG. 5 shows a flowchart for determining whether the data is invalid according to an embodiment of this disclosure.

FIG. 6 shows a diagram illustrating a relationship between a number of conducted memory cells for a valid data, a number of conducted memory cells for an invalid data and a preset value when applying a particular read voltage to the data segment according to an embodiment of this disclosure.

FIG. 7 shows a diagram illustrating a relationship between a number of conducted memory cells for a valid data, a number of conducted memory cells for an invalid data and a preset value when applying multiple read voltages to the data segment according to an embodiment of this disclosure.

FIG. 8 shows a diagram for setting a predetermined condition according to another embodiment of this disclosure.

### DETAILED DESCRIPTION

In the following detailed description, for purposes of explanation, numerous specific details are set forth in order to provide a thorough understanding of the disclosed embodiments. In those embodiments, at least one voltage is applied to memory cells of a data segment of a non-volatile memory to obtain a number of the conducted memory cells of the data segment, such that whether the data is an invalid data is determined. It will be apparent, however, that one or more embodiments may be practiced without these specific details. In other instances, well-known structures and devices are schematically shown in order to simplify the drawing.

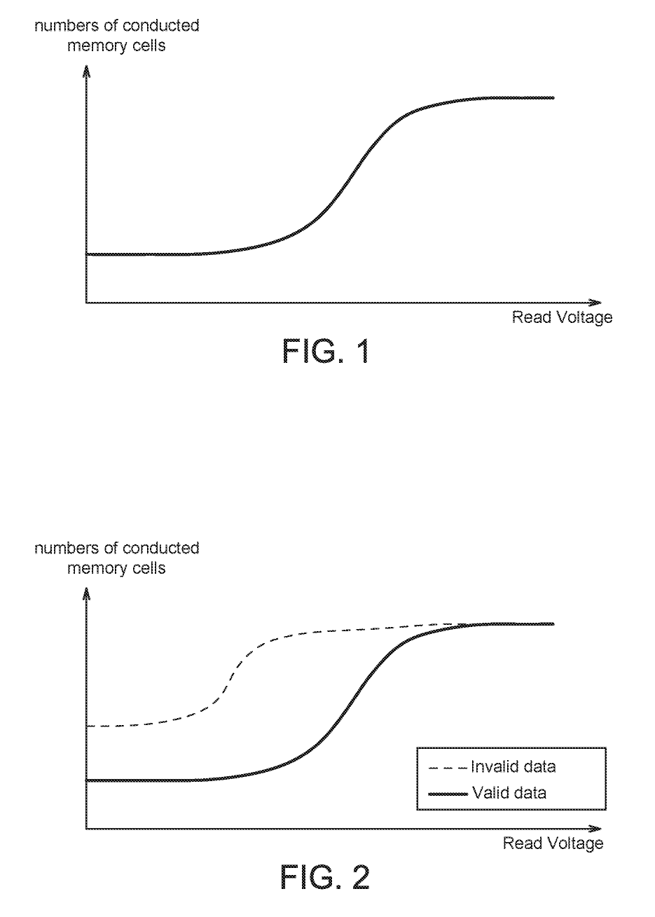

Please refer to FIG. 1. FIG. 1 shows a diagram illustrating a distribution of numbers of conducted memory cells corresponding to different read voltages applied to data segments of the non-volatile memory. The non-volatile memory can be segmented into a plurality of data segments. For example, a data segment can be a word line of the non-volatile memory. A data segment also can be a plurality of word lines of the non-volatile memory. The data segment includes a plurality of memory cells. The memory cell can be a single-level cell (SLC) storing 1-bit data, a multi-level cell (MLC) storing 2-bit data, a triple-level cell (TLC) storing 3-bit data, or other types of memory cell.

As shown in FIG. 1, the vertical axis represents a number of conducted memory cells, and the horizontal axis represents the read voltage applied to the memory cells. When progressively applying the read voltage, from low to high, to the data segment of the non-volatile memory, more and more memory cells in this data segment are conducted as the read voltage applied to the data segment increases. All of the memory cells are conducted in this data segment when the applied read voltage is high enough.

The data stored in data segment could be an invalid data, if an interruption occurs or other factors effect during reading, writing or erasing the non-volatile memory. The reason to make the data invalid, for example, could be an interruption occurring in a process of writing data which makes the data be written incompletely. The reason to make the data invalid, for example, could be an interruption occurring in a process of erasing data which makes the data be erased incompletely. Therefore, the data stored in the data segment could be the invalid data if the data stored in the data segment is incomplete.

In the embodiments of present invention, the data stored in the data segment can be classified into a valid data and an invalid data. The valid data means that the data stored in the data segment is complete; thus, during reading the data, errors in the valid data can be recovered by performing an error recover procedure. The invalid data means that the data stored in the data segment is incomplete; thus, the original data has been lost and cannot be recovered by performing the error recover procedure.

In order to determine whether the data stored in the data segment is an invalid data or not, embodiments of present invention utilize the difference between physical characteristics of the data segment storing the valid data and that of the data segment storing the invalid data. After several examinations, it is found that there is an obvious difference between a distribution curve of numbers of conducted memory cells in the data segment storing the valid data and a distribution curve of numbers of conducted memory cells in the data segment storing the invalid data when applying the read voltage progressively, from low to high, to the data segment of the non-volatile memory.

Please referring to FIG. 2, FIG. 2 shows a distribution of numbers of conducted memory cells corresponding to different read voltages applied to the data segment storing the valid data and the data segment storing the invalid data. The vertical axis represents a number of conducted memory cells, and the horizontal axis represents the read voltage applied to the memory cells. FIG. 2 illustrates two different distribution curves. The solid-line curve represents a distribution curve of a number of conducted memory cells corresponding to different read voltages applied to the data segment storing the valid data. The dotted-line curve represents a distribution curve of a number of conducted memory cells corresponding to different read voltages applied to the data segment storing the invalid data. As shown in FIG. 2, within a particular range of read voltage, when applying appropriate identical read voltages to the data segment storing the valid data and the data segment storing the invalid data respectively, the number of the conducted memory cells for the valid data is different from the number of the conducted memory cells for the invalid data. In other words, based on the aforementioned, whether the data stored in the data segment is the invalid data or not can be determined according to the number of the conducted memory cells after applying appropriate read voltage to the data segment.

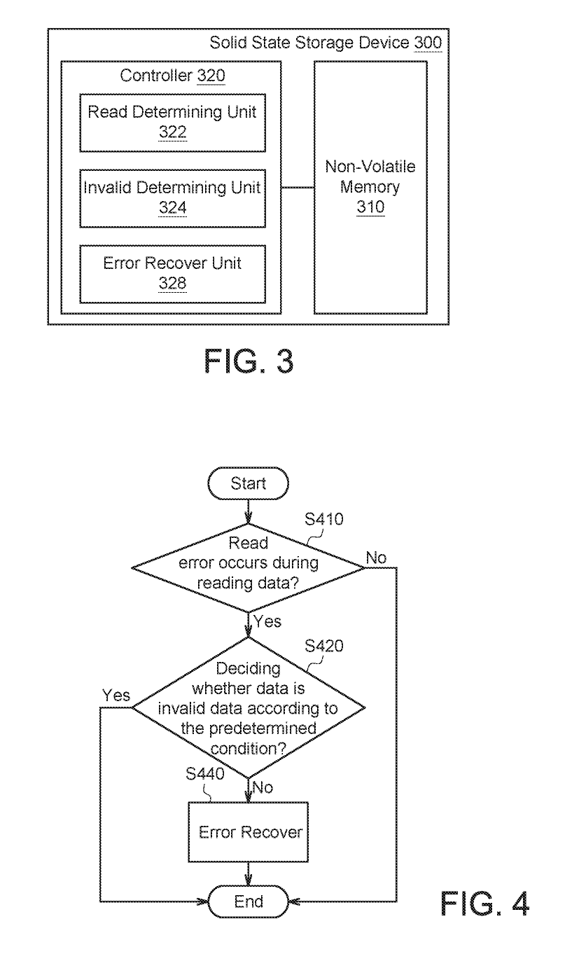

FIG. 3 shows a diagram illustrating a solid state storage device 300 according to an embodiment of this disclosure. The solid state storage device 300 includes a non-volatile memory 310 and a controller 320. The controller 320 is coupled to the non-volatile memory 310. The controller 320 is used to control data access of the non-volatile memory 310 and other operations. The non-volatile memory 310 is the main data storage medium of the solid state storage device 300. The controller 320 can communicate instructions and data to a host device (not shown in FIG. 3) through an external bus outside of the solid state storage device 300.

The controller 320 is used to perform various control procedures or computing procedures. For example, the controller 320 can be a chip, a circuit block in a chip, a circuit board including a plurality of electric elements and a plurality of conductive wires, or a computer readable medium storing a plurality of program codes. In the present embodiment, the controller 320 includes a read determining unit 322, an invalid determining unit 324 and an error recover unit 328. The read determining unit 322 is used for determining whether a read error occurs during reading a data stored in the data segment. The invalid determining unit 324 is used for determining whether the data stored in the data segment is an invalid data. The error recover unit 328 is used for performing an error recover procedure. The read determining unit 322, the invalid determining unit 324 and the error recover unit 328 can be a chip, a circuit block in a chip, a circuit board including a plurality of electric elements and a plurality of conductive wires, or a computer readable medium storing a plurality of program codes.

Please refer to FIG. 4, which illustrates a flowchart for a data processing method according to an embodiment of this disclosure. To clearly illustrate the operation of the various elements of the above-described embodiment and the present embodiment, the data processing method for the solid state storage device is described with the flowchart below. However, those skilled in the art can understand, the data processing method of the present embodiment is applied but not limited to the solid state storage device 300 in FIG. 3, and it is not limited to the order of the steps of the flowchart.

Please refer to FIG. 3 and FIG. 4. According to an embodiment of the present invention, in step S410, the read determining unit 322 in the controller 320 can read a data segment of the non-volatile memory 310 and can determine whether a read error occurs during reading the data stored in the data segment. In an embodiment of the present invention, the read determining unit 322 can take error correction schemes, such as Error-Correcting codes (ECC), Hamming codes, BCH codes, Reed-Solomon codes, and the like, on the read data to perform error correction, and determine whether the read error occurs during reading the data according to a result of error correction. There are lots of the situations that cause the read error to occur during reading the stored data. For example, if there is an offset or loss of the data stored in the data segment due to the environment factors, such as temperature or time, the data stored in the data segment cannot be corrected by an error correction scheme and then the read error occurs during reading the data. Or if the data stored in the data segment is incomplete due to interrupted operations or incomplete operations when reading the data from the data segment, writing the data into the data segment, or erasing the data from the data segment, the incomplete data cannot be corrected by an error correction scheme and then the read error occurs during reading the data.

In step S410, when the read data cannot be corrected by the error correction schemes, the read determining unit 322 determines that the read error occurs during reading the data stored in the data segment. In step S410, when the read data can be corrected by the error correction schemes, the read determining unit 322 determines that no read error occurs during reading the data stored in the data segment, and then the controller 320 obtains the correct read data. If the correct read data is read according to a read instruction from the host device, the controller 320 can transfer the correct read data to the host device.

Next, in step S420, when the read determining unit 322 determines that the read error occurs during reading the data stored in the data segment, the invalid determining unit 324 further determines whether the data is an invalid data according to a predetermined condition. There are lots of situations that cause the data to be the invalid data. For example, when writing the data into the data segment, the data writing operation is interrupted and not complete. Thus, the data is written incompletely and the data stored in the data segment is the invalid data. Or when erasing the data stored in the data segment, the data erasing operation is interrupted and not completed. Thus, the data is erased incompletely and the data stored in the data segment is the invalid data.

After steps S410 and S420, three possible situations of the stored data are determined. The first possible situation, i.e. the determination of step S410 is NO, is that the data stored in the data segment is a valid data and the stored data is read correctly. The second situation (the determination of step S410 is YES and the determination of step S420 is NO) is that the data stored in the data segment is a valid data, but there is an offset or loss of the data stored in the data segment due to the environment factors, such as temperature or time. The stored data cannot be corrected by an error correction scheme when reading the stored data, and then the read error occurs during reading the stored data. The third possible situation (the determination of step S410 is YES and the determination of step S420 is YES) is that the data stored in the data segment is an invalid data. For example, during an operation of writing into, reading from, or erasing from the data segment, the operation is interrupted or not complete, so the data stored in the data segment is incomplete and is the invalid data, and then a read error occurs during reading the stored data.

When the invalid determining unit 324 determines that the data is the invalid data according to the predetermined condition, the controller 320 terminates the process. If the data is read according to the read instruction from the host device, the controller 320 can transfer a result of failing to read the data to the host device. When the invalid determining unit 324 determines that the read error occurs during reading the data, but the data is the valid data according to the predetermined condition, in step S440, the error recover unit 328 performs an error recover scheme to the data. In the embodiment of the present invention, the error recover scheme is different from the error correction scheme. Error correction is to take error correction schemes, such as Error-Correcting codes (ECC), Hamming codes, BCH codes, Reed-Solomon codes, and the like, on the read data to perform error correction. Error recover is to use various reading conditions to re-read the data.

In an embodiment of the present invention, the error recover unit 328 can re-read the data by different reading conditions according to a retry table until no read error occurs during reading the data. The reading conditions can include applying different read voltages, using different error correction codes, or taking different error correction schemes. The error recover unit 328 re-reads the data under different read voltages or takes different error correction codes or error correction schemes on the re-read data to perform error recovery until no read error occurs during reading the data.

In another embodiment of the present invention, the controller 320 can determine whether the data is an invalid data in advance and then determine following data reading procedure. Specifically, when the controller 320 plans to read the data stored in the data segment of the non-volatile memory 310, the invalid determining unit 324 can determine whether the stored data is a valid data according to a predetermined condition in advance. If the stored data is determined to be the invalid data, the controller 320 does not need to read the data stored in the data segment. In addition, if the data is read according to the read instruction from the host device, the controller 320 can transfer a result of failing to read the data to the host device directly. Instead, if the stored data is determined to be the valid data, the controller 320 starts to read the data stored in the data segment, i.e. performing steps S410 and S440.

In this embodiment, because the controller 320 has determined whether the data is the invalid data (step S420) in advance, when the controller 320 performs step S410 and determines that the read error occurs during reading data, the controller can perform the error recovery (step S440) directly without performing step S420 again.

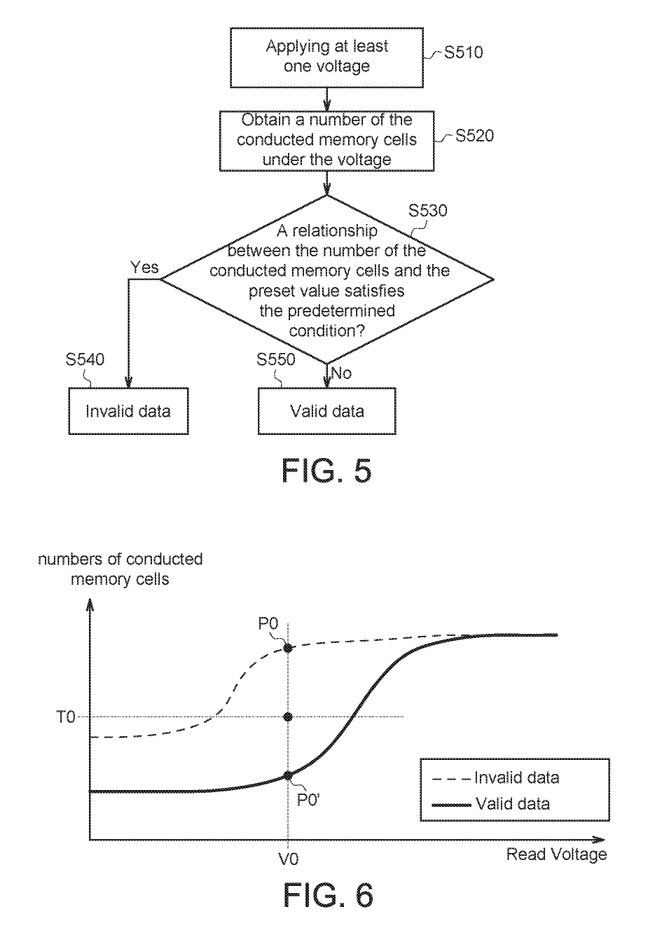

Please refer to FIG. 5 which illustrates a flowchart for determining whether the data is an invalid data. In step S420 of FIG. 4, the invalid determining unit 324 determines whether the data stored in the data segment is the invalid data according to a predetermined condition. Steps S510 to S550 of FIG. 5 further specify details of step S420 of FIG. 4, which determines whether the data is the invalid data. In step S510, the invalid determining unit 324 applies at least one read voltage to the data segment. In step S520, the invalid determining unit 324 obtains a number of the conducted memory cells in this data segment under the read voltage. In step S530, the invalid determining unit 324 judges whether a relationship between the number of the conducted memory cells and a preset value corresponding to the read voltage satisfies a predetermined condition to determine whether the data is the invalid data or the valid data.

FIG. 6 shows a diagram illustrating a relationship between a number of conducted memory cells for the valid data, a number of conducted memory cells for the invalid data and a preset value when applying a particular read voltage to the data segment according to an embodiment of the present invention. The vertical axis represents a number of conducted memory cells, and the horizontal axis represents the read voltage applied to the memory cells. In this embodiment, in step S510, the invalid determining unit 324 applies a read voltage V0 to the data segment. In step S520, the invalid determining unit 324 obtains the number of the conducted memory cells. Next, in step S530, the invalid determining unit 324 judges whether a relationship between the number of the conducted memory cells and a preset value T0 corresponding to the read voltage V0 satisfies the predetermined condition to determine whether the data stored in the data segment is the invalid data or the valid data. In the embodiment illustrated in FIG. 6, under the applied read voltage V0, the number P0 of the conducted memory cells for the invalid data is greater than the preset value T0, and the number P0′ of conducted memory cells for the valid data is smaller than the preset value T0.

Hence, in the embodiment illustrated in FIG. 6, the predetermined condition can be set as that the number of the conducted memory cells is greater than the preset value. By applying the read voltage V0, if the relationship between the number of the conducted memory cells and the preset value T0 satisfies the predetermined condition, i.e. the number of the conducted memory cells is greater than the preset value T0, the invalid determining unit 324 determines that the data stored in the data segment is the invalid data in step S540. Instead, under the read voltage V0, if the relationship between the number of the conducted memory cells and the preset value T0 does not satisfy the predetermined condition, i.e. the number of the conducted memory cells is smaller than the preset value T0, the invalid determining unit 324 determines that the data stored in the data segment is the valid data in step S550.

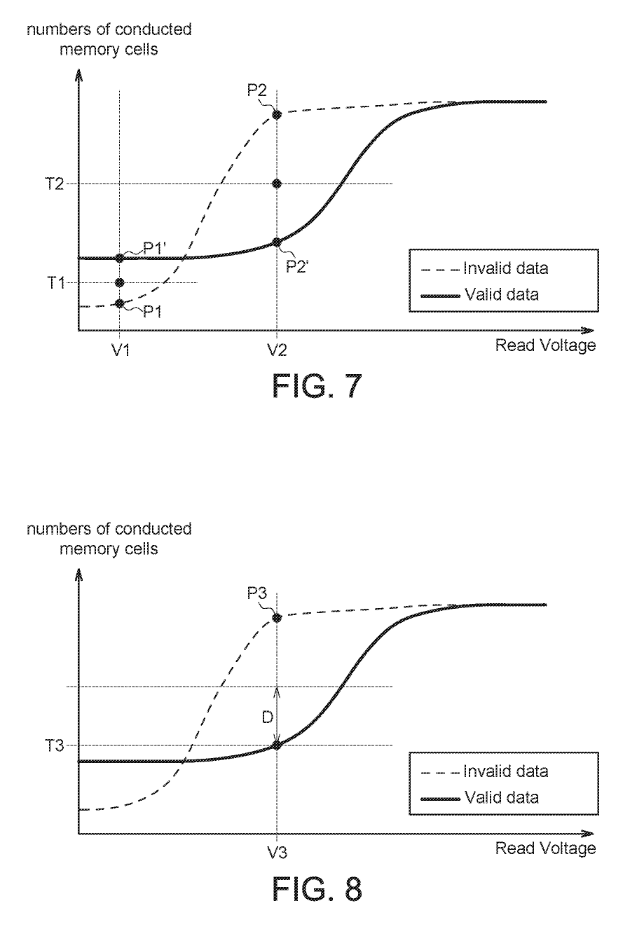

According to another embodiment of the present invention, FIG. 7 shows a diagram illustrating a relationship between a number of the conducted memory cells for the valid data, a number of the conducted memory cells for the invalid data and a preset value when applying multiple read voltages to the data segment of the non-volatile memory. The vertical axis represents a number of the conducted memory cells, and the horizontal axis represents the read voltage applied to the memory cells. In this embodiment, the invalid determining unit 324 applies a first read voltage V1 and a second read voltage V2 separately to the data segment of the non-volatile memory (step S510), and obtains a first number of the conducted memory cells and a second number of the conducted memory cells accordingly (step S520). In this embodiment, the first read voltage V1 and the second read voltage V2 correspond to a first preset value T1 and a second preset value T2 respectively. The invalid determining unit 342 judges whether a relationship between the first number of the conducted memory cells under the first read voltage V1 and the first preset value T1 and a relationship between the second number of the conducted memory cells under the second read voltage V2 and the second preset value V2 satisfy the predetermined condition to determine whether the data is the invalid date or the valid data.

In the embodiment illustrated in FIG. 7, when applying the first read voltage V1, the number P1 of the conducted memory cells for the invalid data is smaller than the first preset value T1, and the number P1′ of the conducted memory cells for the valid data is greater than the first preset value T1. When applying the second read voltage V2, the number P2 of the conducted memory cells for the invalid data is greater than the second preset value T2, and the number P2′ of the conducted memory cells for the valid data is smaller than the second preset value T2. Hence, in the embodiment illustrated in FIG. 7, the predetermined condition can be set as that the first number of the conducted memory cells under the first read voltage V1 is smaller than the first preset value T1, and the second number of the conducted memory cells under the second read voltage V2 is greater than the second preset value T2. When applying the voltages V1 and V2 separately, if a relationship between a number of the conducted memory cells and the according preset value satisfies the predetermined condition advanced above, the invalid determining unit 324 determines that the data stored in the data segment is the invalid data. Instead, when applying the voltages V1 and V2 separately, if a relationship between the number of the conducted memory cells and the according preset value does not satisfy the predetermined condition advanced above, the invalid determining unit 324 determines that the data stored in the data segment is the valid data in step S550.

There are various causes of the situation that the data is the invalid data. Thus, in the embodiments illustrated in FIG. 6 and FIG. 7, different distribution curves of the numbers of the conducted memory cells are obtained when applying different read voltages to the data segment storing the valid data and the data segment storing the invalid data. In one embodiment of the present invention, read voltages, preset values and predetermined conditions are set separately for different distribution curves of the numbers of the conducted memory cells for the valid data and for the invalid data respectively. The read voltage can be a single read voltage or multiple read voltages according to the characteristic of the distribution curve. In another embodiment of the present invention, different distribution curves of the number of the conducted memory cells for the valid data and the number of the conducted memory cells for the invalid data can be analyzed and then be integrated into different types of distribution curve. Various read voltages can be set to satisfy various types of distribution curve according to the characteristic of the types of distribution curve.

According to an embodiment, the distribution curve shown in FIG. 6 could be one type of distribution curve, which uses single read voltage, single preset value and corresponding predetermined condition to determine whether the data stored in the data segment is the invalid data. And, the distribution curve shown in FIG. 7 could be another type of distribution curve, which uses multiple read voltages, multiple preset values and corresponding predetermined condition to determine whether the data stored in the data segment is the invalid data.

FIG. 8 shows a diagram for setting a predetermined condition according to another embodiment of this disclosure. The vertical axis represents a number of conducted memory cells, and the horizontal axis represents the read voltage applied to the memory cells. In this embodiment, the invalid determining unit 324 sets a predetermined difference D. The predetermined condition is that the absolute value of the difference between a number of the conducted memory cells and a preset value is larger than the predetermined difference D. In the embodiment illustrated in FIG. 8, when applying a read voltage V3 to a data segment, if the difference between the number of the conducted memory cells and the preset value T3 is larger than the predetermined difference D, it is determined that data stored in the data segment is an invalid data. In this embodiment, the preset value T3 can be set as the number of the conducted memory cells under the particular read voltage V3 for the valid data.

For example, there are 1,000 memory cells in a dada segment of the non-volatile memory. When the data stored in the data segment is a valid data, the number of the conducted memory cells is 100 under a particular read voltage, and then the preset value T3 is set to 100 and the predetermine difference D is set to 30. Hence, if the number of the conducted memory cells is 200 under the particular read voltage, it is determined that the data stored in the data segment is the invalid data because the absolute value of the difference between the number of the conducted memory cells and the preset value T3 is larger than the predetermined difference D.

In the embodiment of the present invention, at least one particular read voltage is applied to the data segment of the non-volatile memory, the number of the conducted memory cells is obtained, and whether the data stored in the data segment of the non-volatile memory is the invalid data is determined according to a judging result of whether a relationship between the number of the conducted memory cells and the preset value satisfies a predetermined condition. As the embodiments illustrated above, when a read error occurs during reading the data stored in the data segment of the non-volatile memory, whether the data stored in the data segment is the invalid data is determined before performing the error recover procedure. Accordingly, it can avoid to perform unnecessary error recover procedure and to waste computing cost. In addition, it also can save time and improve the efficiency of data processing.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A data processing method for a solid state storage device, wherein the solid state storage device includes a non-volatile memory, the non-volatile memory has at least one data segment, the data segment includes a plurality of memory cells, and the data processing method comprises:
determining whether a data stored in the data segment is an invalid data according to a predetermined condition, wherein the step of determining whether the data stored in the data segment is the invalid data according to the predetermined condition comprises:
applying at least one voltage to the data segment to obtain a number of the conducted memory cells under the voltage, wherein the voltage corresponds to a preset value; and
judging whether a relationship between the number of the conducted memory cells and the preset value satisfies the predetermined condition to determine whether the data is the invalid data.

2. The data processing method according to claim 1, wherein
an error recover procedure is performed on the data if the data is determined not to be the invalid data and a read error occurs during reading the data; and
the error recover procedure is not performed on the data if the data is determined to be the invalid data and the read error occurs during reading the data.

3. The data processing method according to claim 1, wherein if the data stored in the data segment is incomplete, the data stored in the data segment is the invalid data.

4. The data processing method according to claim 1, further comprising:
determining whether a read error occurs during reading the data stored in the data segment;
wherein if the read error occurs during reading the data stored in the data segment, and the data stored in the data segment is determined not to be the invalid data, an error recover procedure is performed on the data,
wherein if the read error occurs during reading the data stored in the data segment, and the data stored in the data segment is determined to be the invalid data, a result of failing to read the data is transferred without performing the error recover procedure on the data.

5. The data processing method according claim 1, wherein the step of determining whether the data stored in the data segment is the invalid date according to the predetermined condition comprises:
applying a first voltage to the data segment to obtain a first number of the conducted memory cells under the first voltage, wherein the first voltage corresponds to a first preset value;
applying a second voltage to the data segment to obtain a second number of the conducted memory cells under the second voltage, wherein the second voltage corresponds to a second preset value; and
determining whether a relationship between the first number and the first preset value and a relationship between the second number and the second preset value satisfy the predetermined condition to determine whether the data is the invalid data.

6. A solid state storage device, comprising:
a non-volatile memory having at least one data segment, the data segment includes a plurality of memory cells; and
a controller, including:
an invalid determining unit for determining whether a data stored in the data segment is an invalid data according to a predetermined condition, wherein the invalid determining unit applies at least one voltage to the data segment to obtain a number of the conducted memory cells, wherein the voltage corresponds to a preset value, and judges whether a relationship between the number of the conducted memory cells and the preset value satisfies the predetermined condition to determine whether the data is the invalid data.

7. The solid state storage device according to claim 6, further comprising:
an error recover unit for performing an error recover procedure,
wherein if the invalid determining unit determines that the data is not the invalid data and a read error occurs during reading the data, the error recover unit performs the error recover procedure on the data; and
if the invalid determining unit determines that the data is the invalid data and the read error occurs during reading the data, the error recover unit does not perform the error recover procedure on the data.

8. The solid state storage device according to claim 6, wherein if the data stored in the data segment is incomplete, the data stored in the data segment is the invalid data.

9. The solid state storage device according to claim 6, further comprising:
a read determining unit for determining whether a read error occurs during reading the data stored in the data segment; and
an error recover unit for performing an error recover procedure,
wherein if the read error occurs during reading the data stored in the data segment, and the data stored in the data segment is determined not to be the invalid data, the error recover procedure is performed on the data,
wherein if the read error occurs during reading the data stored in the data segment, and the data stored in the data segment is determined to be the invalid data, a result of failing to read the data is transferred without performing the error recover procedure on the data.

10. A data processing method for a solid state storage device, wherein the solid state storage device includes a non-volatile memory, the non-volatile memory has at least one data segment, the data segment includes a plurality of memory cells, and the data processing method comprises:
determining whether a data stored in the data segment is an invalid data according to a predetermined condition; and
performing an error recover procedure on the data if the data is determined not to be the invalid data and a read error occurs during reading the data;
wherein the step of performing the error recover procedure is not performed on the data if the data is determined to be the invalid data and the read error occurs during reading the data.

11. The data processing method according claim 10, wherein the step of determining whether the data stored in the data segment is the invalid date according to the predetermined condition comprises:
applying at least one voltage to the data segment to obtain a number of the conducted memory cells under the voltage, wherein the voltage corresponds to a preset value; and
judging whether a relationship between the number of the conducted memory cells and the preset value satisfies the predetermined condition to determine whether the data is the invalid data.
